(19) United States
(12) Patent Application Publication
(10) Pub. No.: US 2007/0103850 A1
(43) Pub. Date: May 10, 2007

(54) Cage type battery terminal

(75) Inventors: Dawn Melman, Delkalb, IL (US); Robert Miller, Schaumburg, IL (US)

Correspondence Address: FOLEY AND LARDNER LLP;SUITE 500, 3000 K STREET NW, WASHINGTON, DC, 20007, US

(73) Assignee: Omron Automotive Electronics, Inc.

(21) Appl. No.: 11/528,363

(22) Filed: Sep. 28, 2006

Related U.S. Application Data
(60) Provisional application No. 60/721,133, filed on Sep. 28, 2005.

(51) Int. Cl. H05K 5/00

(52) U.S. Cl. 361/679; 340/825.69; 341/176

(57) ABSTRACT

An embodiment of the present invention includes a cage type battery terminal that is utilized in conjunction with a battery pad on a printed circuit board. In a first exemplary embodiment of the present invention, there is a remote keyless entry key fob. Key fob may include a chain with a key ring configured to connect to car keys. The key fob may include buttons, which may be utilized to activate the key fob to send a signal to a vehicle to unlock a car door, or send a signal to a vehicle to open a trunk.

### CROSS-REFERENCE TO RELATED PATENT APPLICATIONS

This application claims priority to U.S. Provisional Patent Application No. 60/721,133, filed on Sep. 28, 2005, to inventors Dawn Melman and Robert Miller of Illinois, U.S.A., the contents of that application being incorporated herein by reference in its entirety.

### BACKGROUND OF THE INVENTION

Electronic key fobs may be used for remote keyless entry systems in vehicles. Early electronic key fobs operated using infrared. More recent models use challenge-response authentication over radio frequency, and thus are harder to copy and do not need line of sight to operate as opposed to some of their ancestral infrared key fobs.

Remote keyless entry key fobs are increasingly becoming popular for use by drivers to unlock and sometimes even open the doors/trunks of their vehicle without inserting a key into the door/trunk. Modem remote keyless access key fobs permit a user to depress a button, etc. to activate the key fob. Upon activation of a remote keyless entry key fob by a user, the key fob emits a radio signal, this radio signal being received by a receiver in the user's vehicle. The receiver analyzes the signal and determines whether the signal is indicative of a recognized signal to command an onboard keyless entry system to unlock doors/open doors/open trunks, etc.

Key fobs are increasingly used in apartment buildings and condominium buildings for access to common areas (i.e. lobby doors, storage areas, fitness room, pools, etc.). Some may be programmed to allow access only to those areas in which the tenant or owner is permitted to access, or only within certain time frames, etc.

Telecommuters may also use an electronic device known as a key fob that provides one part of a three way match to log in over an unsecure network connection to a secure network. This kind of key fob may have a keypad on which the user must enter a PIN to retrieve an access code, or it could be a display-only device such as a VPN token that algorithmically generates security codes as part of a challenge/response authentication system.

Key fobs typically require a battery and include a circuit board. Typically the battery and the circuit board are enclosed in a housing of the key fob. Key fobs are typically carried in the user's pocket, purse, etc., and are often subject to jostling, shaking, vibration and shock. Further, key fobs are typically also connected to keys, especially ignition keys, and thus often hang from the ignition key while the ignition key is in the ignition switch while the user is driving his/her car. During driving, the key fob will move back and forth as the vehicle experiences acceleration and deceleration (due to change in forward velocity, bumps, change in direction, etc.), and also experience vibration. These movements/shocks/vibrations induce movement between the battery (usually a button cell battery) powering the key fob and battery connectors of the key fob. Moreover, these phenomena sometimes induce flexing of the housing of the key fob which may create an opening in the electrical circuit of which the battery is part (i.e., a space opens between battery terminals/pads and terminals of the battery). Even when no space is opened, fretting corrosion may occur, which may be induced by the movement/shocks/vibrations of the key fob. Fretting corrosion may lead to poor reliability with respect to powering the key fob. In some key fobs, connector grease is utilized to address these problems. However this has been found undesirable in many instances.

### SUMMARY OF THE INVENTION

In a first embodiment of the invention, there is a key fob, comprising a plastic housing; a circuit board; and a battery cage attached directly to the circuit board and directly on a surface of the circuit board, wherein the circuit board assembly includes a battery pad on the circuit board, the battery cage includes a battery terminal, and the circuit board with the battery cage attached directly to the circuit board and directly on the surface of the circuit board is housed in the housing in such a manner that the housing does not contact the battery cage.

In another embodiment of the invention, there is a device as described above or below, where at least one button configured to be depressed by a user and to at least one of close and open a circuit, the circuit being at least in part contained on the circuit board thereby generating a radio signal. In another embodiment of the invention, there is a device as described above or below, which includes a circuit board; and a battery cage attached directly to the circuit board and directly on a surface of the circuit board, wherein the circuit board assembly includes a negative battery pad on the circuit board, and the battery cage includes a positive battery terminal.

In another embodiment of the invention, there is a device as described above or below, the battery cage includes a battery dock configured to receive a battery of cylindrical configuration, the battery dock comprising a first arm; a second arm opposite the first arm with respect to the battery dock; and a third arm. In another embodiment of the invention, there is a device as described above or below, where the first and second arms form lateral sides of the battery dock, and wherein the third arm forms a longitudinal side of the battery dock, wherein lateral and longitudinal directions are the same as the respective directions of the battery of cylindrical configuration when docked in the dock. In another embodiment of the invention, there is a device as described above or below, where the circuit board forms another longitudinal side of the battery dock opposite the third arm. In another embodiment of the invention, there is a device as described above or below, where the first arm, the second arm, the third arm and the circuit board are configured to cooperate to trap a button cell battery in the battery dock.

In another embodiment of the invention, there is a device as described above or below, where at least the first arm and the third arm are configured to elastically deform to receive the button cell battery and trap the button cell battery in the battery dock. In another embodiment of the invention, there is a device as described above or below, where the third arm includes a positive battery terminal which is in electrical communication with components on the printed circuit board. In another embodiment of the invention, there is a device as described above or below, where the circuit board assembly is configured to complete a circuit between the negative battery pad and the positive battery terminal of the battery cage when the button cell battery is trapped in the battery dock. In another embodiment of the invention, there is a device as described above or below, where the negative battery pad on the circuit board is integral with the circuit board. In another embodiment of the invention, there is a device as described above or below, where the circuit board is a printed circuit board.

In another embodiment of the invention, there is a device as described above or below, where the battery cage is at least one of directly soldered to the circuit board, directly bolted to the circuit board, and directly riveted to the circuit board.

In another embodiment of the invention, there is a device as described above or below, where the battery cage comprises a single piece of conductive material.

In another embodiment of the invention, there is a device as described above or below, where the battery cage comprises a single piece of conductive metal, the metal being plastically deformed to be in the form of the battery cage, the metal further being configured to elastically deform to receive a button cell battery and trap the button cell battery between the battery cage and the circuit board.

In another embodiment of the invention, there is a device as described above or below, including a button cell battery including a positive terminal and a negative terminal, the negative terminal being in direct contact with and directly on the circuit board.

### BRIEF DESCRIPTION OF THE DRAWINGS

The application file contains at least one drawing executed in color. Copies of this patent or patent application publication with color drawing(s) will be provided by the Office upon request and payment of necessary fee.

FIG. 1 is an isometric schematic of a key fob according to an embodiment of the present invention.

FIG. 2 is a cross-sectional view of the key fob presented in FIG. 1.

FIG. 3 is an isometric schematic of a circuit board assembly utilized in a key fob according to an embodiment of the present invention.

FIG. 4-9 present various views of a plurality of embodiments of a battery cage utilized in some embodiments of the present invention.

FIGS. 10-11 present two views of a battery cage attached to a circuit board according to an embodiment of the present invention.

FIG. 12 presents a circuit diagram of a circuit board utilized in an embodiment of the present invention.

FIG. 13 presents a schematic of a printed circuit board utilized in an embodiment of the present invention.

FIG. 14 presents a schematic of a vehicle assembly including a key fob according to an embodiment of the present invention.

### DETAILED DESCRIPTION OF SOME EMBODIMENTS

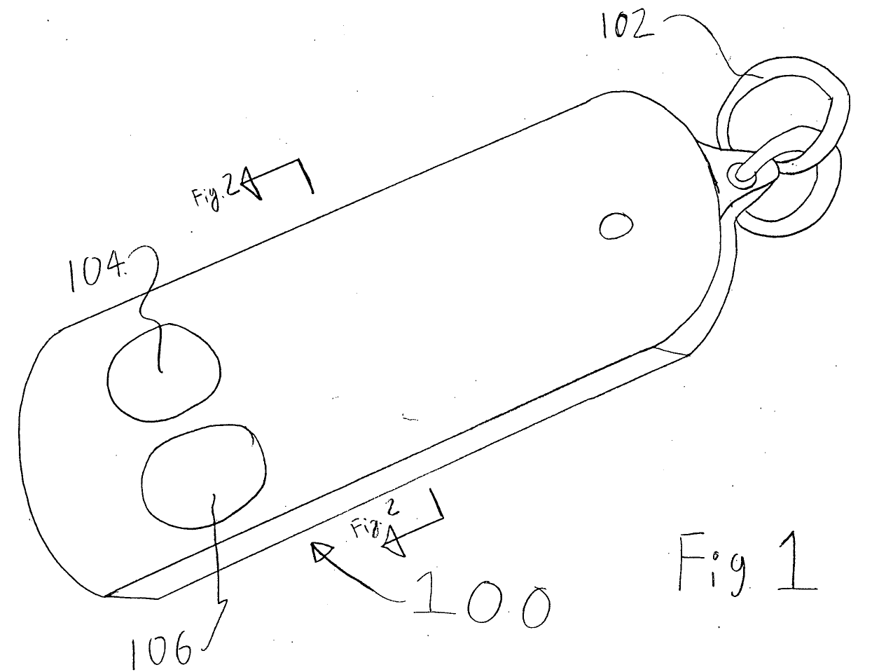

In a first exemplary embodiment of the present invention, as may be seen in FIG. 1, there is a remote keyless entry key fob 100. Key fob 100 includes a chain 102 with a key ring (not shown) configured to connect to car keys. The key fob 100 may include buttons 104 and 106, which may be utilized to activate the key fob 100 to send a signal to a vehicle to unlock a car door (button 104), or send a signal to a vehicle to open a trunk (button 106). The key fob 100 may include additional buttons or fewer buttons, and may include no buttons at all (instead utilizing heat sensors, etc.).

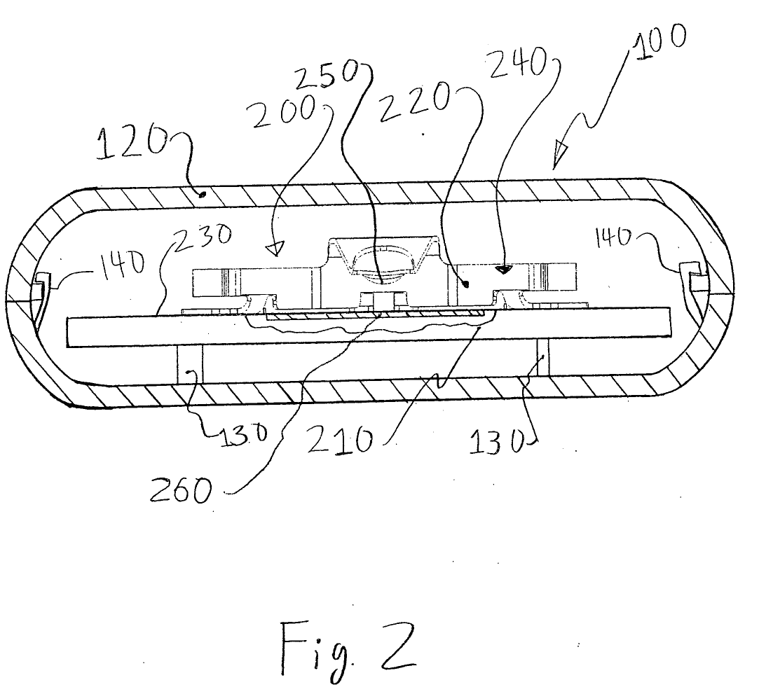

FIG. 2 depicts an exaggerated and modified cross-sectional view of the key fob 100 depicted in FIG. 1. As may be seen, the key fob 100 includes a key fob housing 120 which protects a circuit board assembly 200 which is supported by support pedestals 130. In an exemplary embodiment of the key fob 100, the housing 120 is formed from, hard plastic, and the support pedestals 130 may be integrally formed with the housing 120 during an injection molding operation or the like. In some embodiments, the housing 120 is formed in two parts, the parts being held together by latch assemblies 140, the components of which may be integrally formed with the housing 120, just as may be the case with the pedestals 130.

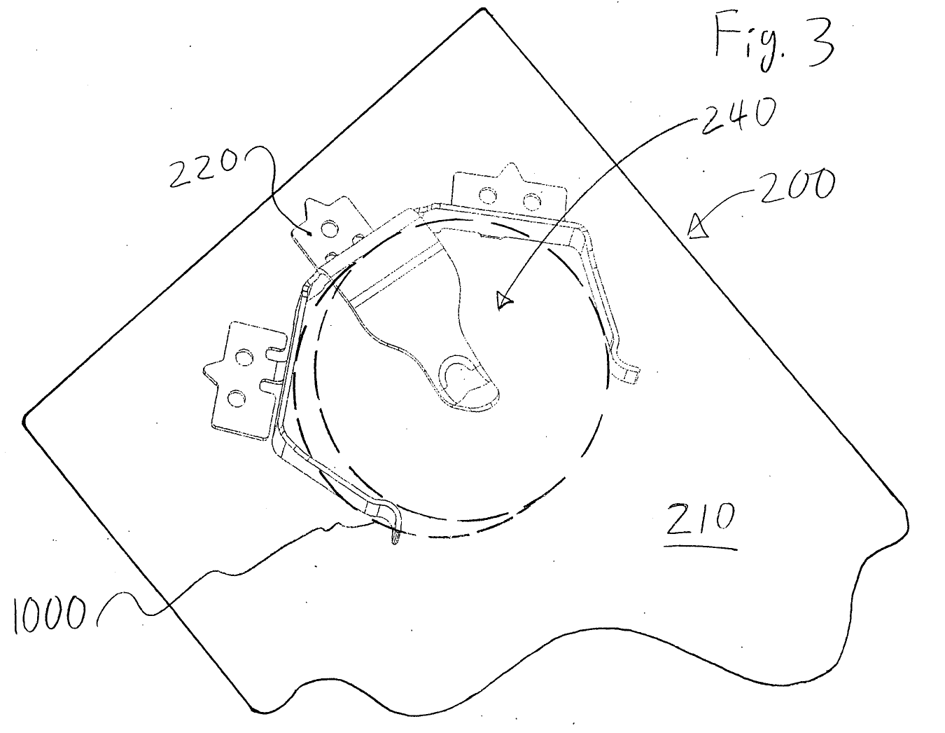

In some embodiments of the present invention, the circuit board assembly 200 includes a circuit board 210 and a battery cage 220 attached directly to the circuit board 210 and directly on the top surface 230 of the circuit board 210. The battery cage 220 is configured to provide a battery dock 240 for a button cell battery 1000 (although in other embodiment, other cage designs may be utilized for other types of batteries) and secure/trap the button cell battery 1000 in the battery dock 240, as may be seen in FIG. 3, where the battery 1000 is presented in dashed line format.

As may be seen, an embodiment of the present invention includes a cage type positive battery terminal that is utilized in conjunction with a negative battery pad on a printed circuit board. Specifically, in some embodiments, the battery cage 220 includes a positive battery terminal 250 configured to form an electrical contact with the battery 1000 secured in the battery dock 240. The battery cage 220 is further in electrical contact with circuitry on the circuit board 210, thus permitting current to flow between the positive terminal of the battery 1000 and the circuit board 210, through the positive terminal 250 of the battery cage 220.

The circuit board assembly 200 may also include a negative battery pad 260 on the circuit board 210. This negative battery pad 260 is also configured to form an electrical contact with the battery 1000. However, the negative battery pad 260 is configured to permit current to flow between the negative terminal of the battery 1000 and the circuit board 210, through the negative battery pad 260. Accordingly, in some embodiments, the circuit board assembly is configured to complete a circuit between the negative battery pad 260 and the positive battery terminal 250 when the button cell battery is trapped in the battery dock (discussed in greater detail below). In some embodiments of the present invention, the negative terminal pad 260 is in the circuit board 210 and directly on the surface 230 of the circuit board 210. In some embodiments, the negative terminal pad 260 is in the circuit board 210 and forms part of the surface 230, and is thus integral with the circuit board. It is noted that in other embodiments of the invention, the battery may be reversed, such that the pad is a positive pad and the cage contains the negative battery terminal.

Some of the embodiments relating to the battery dock 240 will now be described.

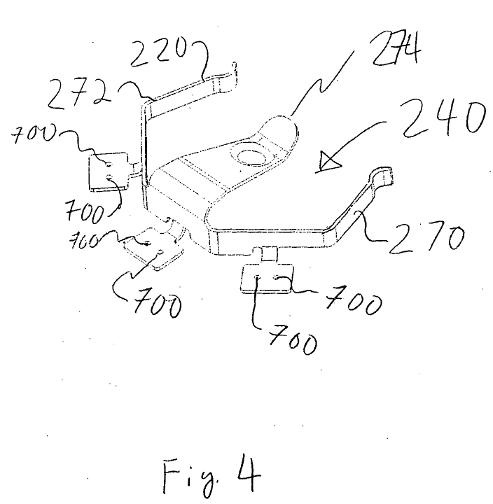

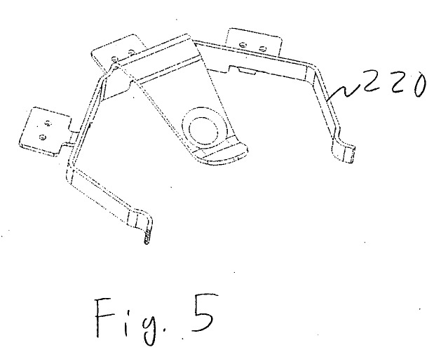

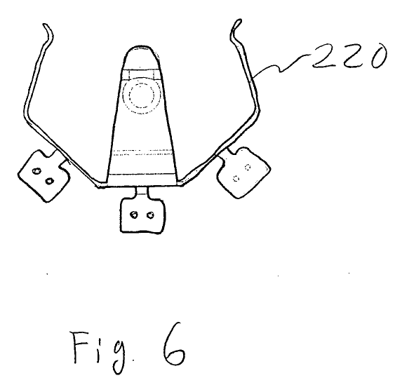

As may be seen in FIGS. 2-3 and as detailed above, the battery cage 220 includes a battery dock 240 configured to receive a battery of cylindrical configuration (battery 1000). As is depicted in FIGS. 4-6, the battery cage 220 includes a first arm 270, a second arm 272 opposite the first arm 270 with respect to the battery dock 240, and a third arm 274. In this embodiment of the invention, the first and second arms 270/272 form lateral sides of the battery dock 240, and the third arm 274 forms a longitudinal side of the battery dock. Here, the lateral and longitudinal directions are the same as the respective directions of a battery of cylindrical configuration when docked in the battery dock 240. That is, with reference to FIG. 3, the lateral sides of the battery dock 240 are the sides that “face” the cylindrical surface(s) of the battery 1000 (i.e., the curved surface of the battery 1000), and the longitudinal sides of the battery dock 240 are the sides that “face” the flat surfaces (ends) of the battery 1000 (i.e., the top and bottom of the battery where the battery terminals are located/the surfaces of the battery that are essentially normal to the axis of the cylinder). When the battery cage 220 is attached to a circuit board 210, as may be seen in FIG. 3 for example, the circuit board 210 forms another longitudinal side of the battery dock opposite the third arm 274.

The arms 270/272/274 and the circuit board 210 are configured to cooperate together to trap/secure the button cell battery in the battery dock 240. By way of example only and not by way of limitation, the material of the battery cage 210 may be of a spring-type material (i.e., it elastically deforms over an expected range of deformations sufficient for use). In some embodiments, at least one of the first and second arms 270/272 and the third arm 274 are configured to elastically deform to receive the button cell battery 1000 and trap the button cell battery 1000 in the battery dock 240. In such embodiments, as the button cell battery 1000 is pushed into the battery dock 240 from the outside (in an exemplary embodiment, the battery cell 1000 is slid along the surface 230 of the circuit board 210), the increasing diameter of the battery cell 1000 (from the perspective of the tips of the arms 270/272) forces one or both of the arms 270/272 away from the other at least until the battery cell 1000 may be fully inserted into the dock 240. As the diameter of the battery cell 1000 decreases (from the perspective of the tips of the arms 270/272), the battery cell 1000 becomes trapped in the dock 240. The third arm 274 elastically deflects upwards as the battery is being inserted into the dock 240, thus providing a compressive force onto the battery cell 1000 in the longitudinal direction. This enhances electrical contact between the circuit board assembly 200 and the battery 1000.

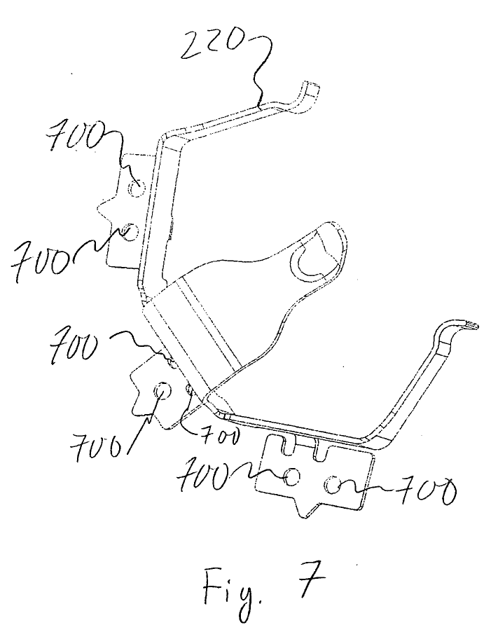

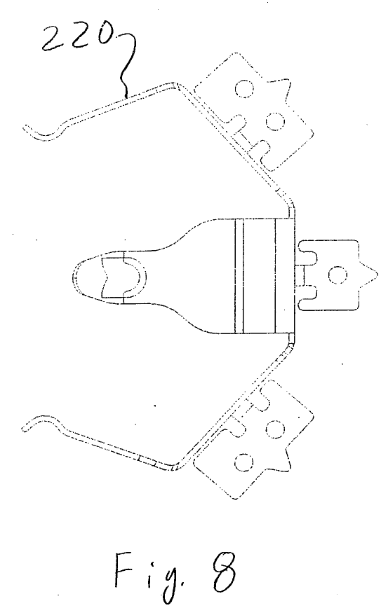

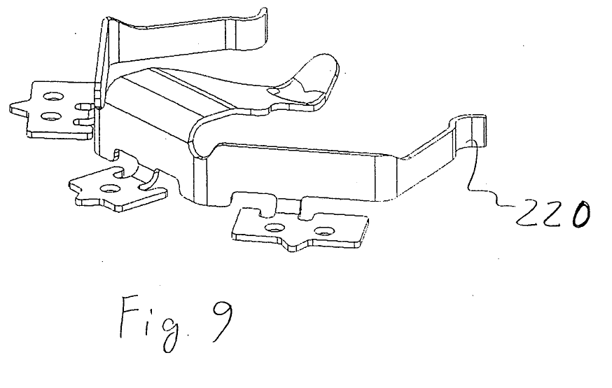

FIGS. 7-9 depict an alternate design of the battery cage 220.

In some embodiments of the present invention, the battery cage 220 design is such that it minimizes and/or eliminates micro movement of the terminal(s) in relation to the battery 1000. This may reduce/eliminate fretting corrosion, at least at the battery-terminal interface(s). The cage design may be configured to maintain a constant, low contact resistance electrical connection between the circuit of the circuit board assembly 200 and the battery 1000. This will reduce the occurrence of/prevent intermittent or even sustained loss of power to the circuit board. Such a configuration provides ease of battery insertion and ease of batter replacement, in that the battery 1000 may simply be slid in (and out) of the battery dock 240.

As may be seen in FIG. 2, embodiments of the present invention include designs where the battery terminal(s) are decoupled from the housing 120 of the key fob 100. That is, in contrast to other key fobs, the battery cage 220 only structurally contacts the circuit board 210 (and, of course, the battery 1000 when inserted in the dock 240). Indeed, in the embodiments depicted in the FIGS., the battery cage 220 is part of the circuit board assembly 200. By decoupling the battery terminals from the housing 120 of the key fob 100, movement between the battery terminals and the battery 1000 is reduced/eliminated because the flexing of the housing 120 is effectively not transferred to the battery terminal, and thus the connection is not disturbed/is less likely to be disturbed via flexing of the housing 120 that results during normal usage/exposure to the normal environment of the key fob 1000.

Embodiments of the present invention permit low cost manufacture of the battery terminal/circuit board assembly. In this regard, the present invention provides ease of manufacture/assembly of the terminal 220 onto the circuit board 210. In some embodiments of the present invention, the cage 220 may be attached to the circuit board 210 and reflow soldered with the rest of the electronic components on the circuit board. That is, some embodiments do not require a separate process to solder or otherwise attach the cage 220 to the circuit board 210—the cage 220 may be attached to the circuit board during the process of reflow soldering other components to the circuit board. It is noted that while some embodiments of the invention utilize direct soldering of the cage 220 to the circuit board 210, other embodiments utilize direct bolting, direct riveting, etc., of the cage 220 to the circuit board 210.

In some embodiments of the invention, the battery cage self-centers during the process of attaching the cage 220 to the circuit board 210. In this regard, in some embodiments of the invention, the cage 220 includes holes 700 (see FIGS. 4 and 7) that are in pads of the cage 220. During attachment of the cage 220 to the circuit board 210, solder from a solder pads on the circuit board may flow through the holes 700, which may allow the cage to self-center on the solder pads of the circuit board 210 even though the cage was not originally centered exactly on the solder pads.

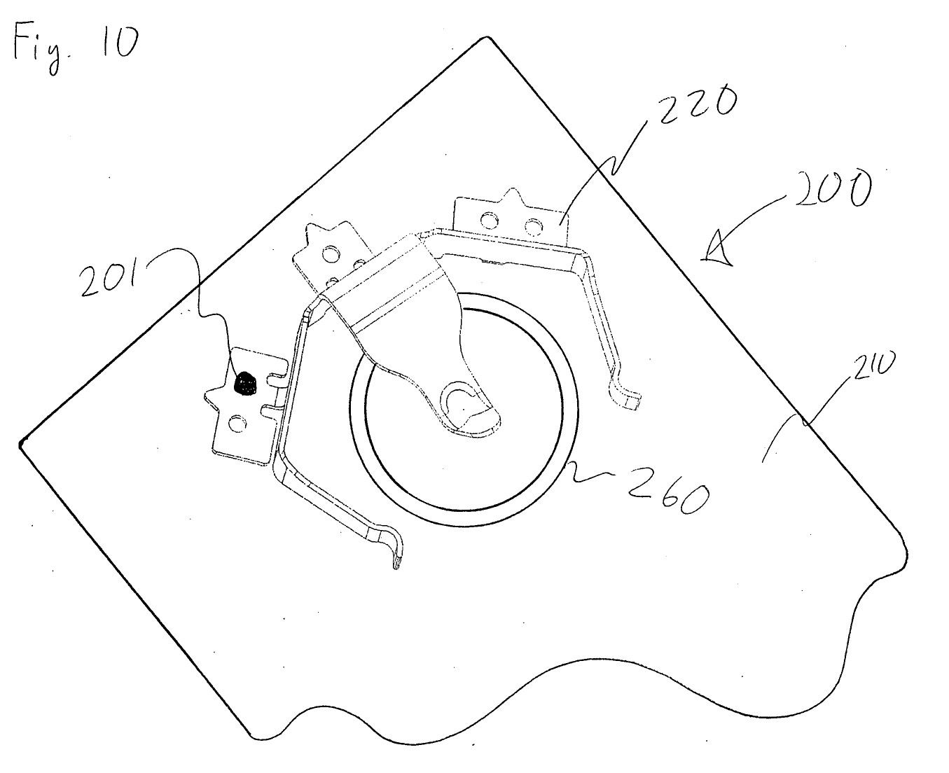

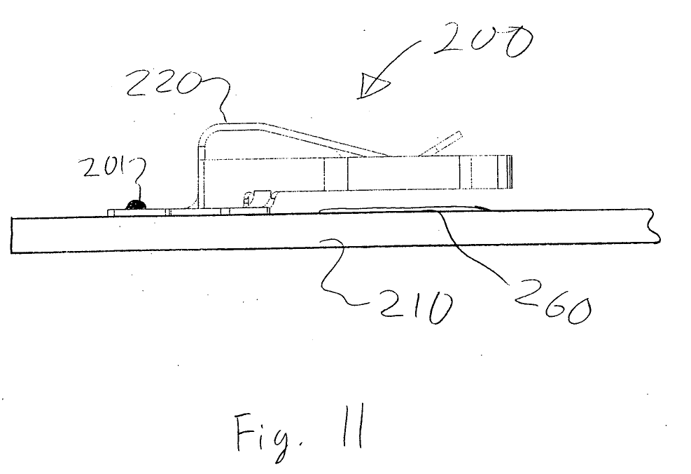

FIGS. 10 and 11 depict battery cages 220 soldered to the circuit board 210, with element 201 being a bead of solder.

The battery cage may be manufactured from a single piece of conductive material, such as metal. In an exemplary embodiment, a flat pattern for the cage 220 is cut out or otherwise formed in a piece of flat, relatively thin material, and the material is then plastically deformed to be in the form of the battery cage 220. In this regard, FIG. 4 presents a view of the cage 220 from which this concept may be readily extrapolated in view of, for example, known metal stamping/bending technologies.

Embodiments of the present invention utilizing the designs depicted in the figures and variations thereof typically provide advantages over through-hole battery terminal designs in that through-hole battery terminal designs interfere with components on the other side of a circuit board (this is especially the case with respect to a printed circuit board). In contrast, utilizing the surface mount design as taught herein eliminates possible interference with components on the other side of the circuit board, at least with respect to a double sided circuit board.

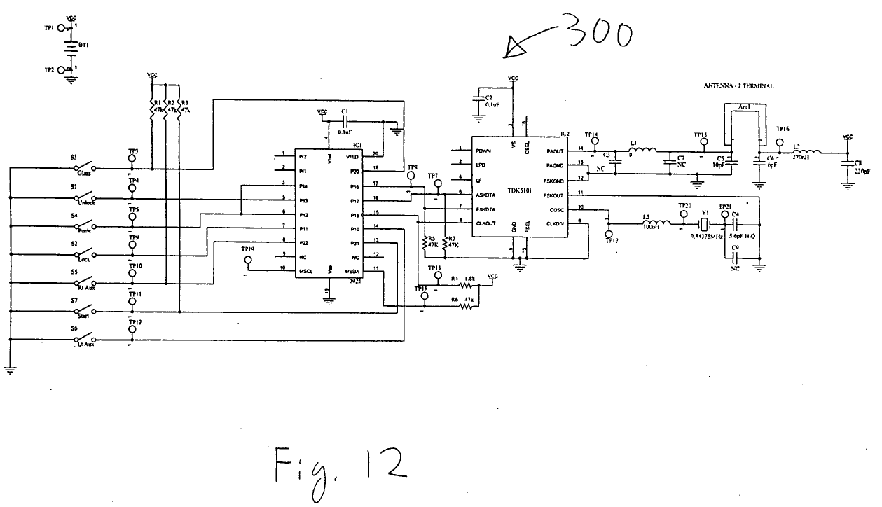

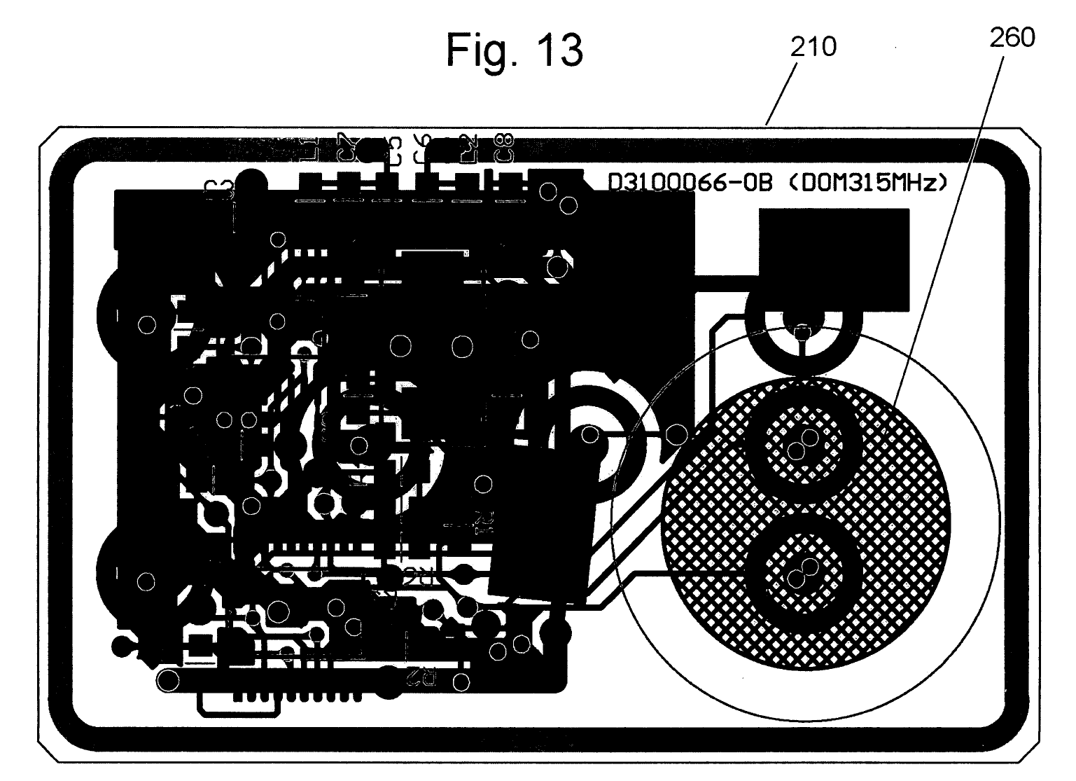

FIG. 12 depicts a wiring diagram of a circuit 300 that may be utilized in the circuit board 210 of the present invention. The circuit 300 depicted in FIG. 12 is a circuit for a remote keyless entry key fob with multiple functions (e.g., unlock, car start, panic, auxiliary functions, etc.) FIG. 13 depicts a schematic of a printed circuit board according to an embodiment of the present invention. In this regard, it is noted that printed circuit boards may be used for the circuit board 210 described herein.

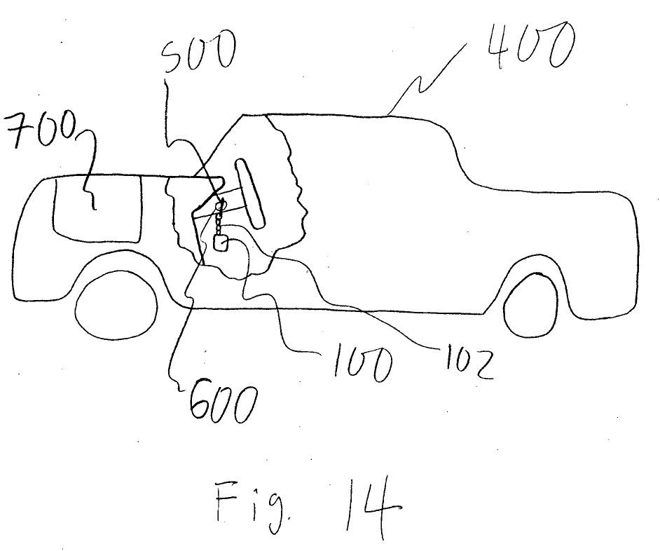

FIG. 14 depicts an embodiment of the present invention that includes a vehicle assembly comprising a vehicle 400 and a key fob 100. In this embodiment, the key fob includes a key chain 102 which is attached to a key 500 that is configured to be inserted into an ignition 600 of the car vehicle and activate an engine 700 of the car vehicle when the key 500 is turned to activate the ignition.

Given the disclosure of the present invention, one versed in the art would appreciate that there are other embodiments and modifications within the scope and spirit of the present invention. Accordingly, all modifications attainable by one versed in the art from the present disclosure within the scope and spirit of the present invention are to be included as further embodiments of the present invention.

What is claimed is:

1. A key fob, comprising:
a plastic housing;
a circuit board; and
a battery cage attached directly to the circuit board and directly on a surface of the circuit board, wherein
the circuit board assembly includes a battery pad on the circuit board,
the battery cage includes a battery terminal, and
the circuit board with the battery cage attached directly to the circuit board and directly on the surface of the circuit board is housed in the housing in such a manner that the housing does not contact the battery cage.

2. The key fob of claim 1, further comprising:
at least one button configured to be depressed by a user and to at least one of close and open a circuit, the circuit being at least in part contained on the circuit board thereby generating a radio signal.

3. A circuit board assembly, comprising:
a circuit board; and
a battery cage attached directly to the circuit board and directly on a surface of the circuit board, wherein
the circuit board assembly includes a negative battery pad on the circuit board, and
the battery cage includes a positive battery terminal.

4. The circuit board assembly of claim 3, wherein the battery cage includes a battery dock configured to receive a battery of cylindrical configuration, the battery dock comprising:
a first arm;
a second arm opposite the first arm with respect to the battery dock; and
a third arm.

5. The circuit board assembly of claim 4, wherein the first and second arms form lateral sides of the battery dock, and wherein the third arm forms a longitudinal side of the battery dock, wherein lateral and longitudinal directions are the same as the respective directions of the battery of cylindrical configuration when docked in the dock.

6. The circuit board assembly of claim 5, wherein the circuit board forms another longitudinal side of the battery dock opposite the third arm.

7. The circuit board assembly of claim 6, wherein the first arm, the second arm, the third arm and the circuit board are configured to cooperate to trap a button cell battery in the battery dock.

8. The circuit board assembly of claim 7, wherein at least the first arm and the third arm are configured to elastically deform to receive the button cell battery and trap the button cell battery in the battery dock.

9. The circuit board assembly of claim 7, wherein the third arm includes a positive battery terminal which is in electrical communication with components on the printed circuit board.

10. The circuit board assembly of claim 9, wherein the circuit board assembly is configured to complete a circuit between the negative battery pad and the positive battery terminal of the battery cage when the button cell battery is trapped in the battery dock.

11. The circuit board assembly of claim 3, wherein the negative battery pad on the circuit board is integral with the circuit board.

12. The circuit board assembly of claim 11, wherein the circuit board is a printed circuit board.

13. The circuit board assembly of claim 3, wherein the battery cage is at least one of directly soldered to the circuit board, directly bolted to the circuit board, and directly riveted to the circuit board.

14. The circuit board assembly of claim 3, wherein the battery cage comprises a single piece of conductive material.

15. The circuit board assembly of claim 3, wherein the battery cage comprises a single piece of conductive metal, the metal being plastically deformed to be in the form of the battery cage, the metal further being configured to elastically deform to receive a button cell battery and trap the button cell battery between the battery cage and the circuit board.

16. The circuit board assembly of claim 3, further comprising a button cell battery including a positive terminal and a negative terminal, the negative terminal being in direct contact with and directly on the circuit board.

17. A key fob, comprising:
a housing; and
a circuit board assembly according to claim 3.

18. A circuit board assembly, comprising:
a circuit board;
a battery cage; and
a button battery including a positive terminal and a negative terminal,
wherein one of the positive terminal and negative terminal is in direct contact with and directly on a surface of the circuit board.

19. The circuit board assembly of claim 18, further including a negative battery pad that is integral with the circuit board, wherein the negative terminal of the button battery is in direct contact with the negative battery pad.

20. The circuit board assembly of claim 18, wherein the battery cage includes a positive battery terminal that is in direct contact with the positive terminal of the button battery.

21. A key fob, comprising:
a housing; and
a circuit board assembly according to claim 18.

22. A method of manufacturing a circuit board assembly, comprising the actions of:
obtaining a circuit board including a first surface;
obtaining a battery cage;
placing battery cage directly on the first surface of the circuit board; and
adhering the battery cage to the first surface of the circuit board.

23. The method of manufacturing a circuit board assembly according to claim 22, further comprising the action of adhering at least one electronic component to the circuit board, wherein the action of adhering the battery cage to the surface of the circuit board occurs at the same time that the at least one electronic component is adhered to the circuit board.

24. The method of manufacturing a circuit board assembly according to claim 22, wherein the action of adhering the battery cage to the surface of the circuit board includes reflow soldering the battery cage to the surface of the circuit board, the method further comprising the action of reflow soldering at least one electronic component to the circuit board, wherein the action of reflow soldering the battery cage to the surface of the circuit board occurs at the same time that the at least one electronic component is reflow soldered to the circuit board.

25. The method of manufacturing a key fob, comprising:
executing the actions of claim 22; and
obtaining a key fob housing and placing the circuit board with the battery cage adhered to the circuit board in the key fob housing.

26. A circuit board assembly, comprising:
a battery;
a circuit board; and
a means for holding the battery in electrical communication with the circuit board.
